(19) United States
(12) Patent Application Publication
(10) Pub. No.: US 2007/0180916 A1
(43) Pub. Date: Aug. 9, 2007

(54) Capacitive micromachined ultrasound transducer and methods of making the same

(75) Inventors: Wei-Cheng Tian, Clifton Park, NY (US); Lowell Scott Smith, Niskayuna, NY (US); Ching-Yeu Wei, Niskayuna, NY (US); Robert Gideon Wodnicki, Niskayuna, NY (US); Rayette Ann Fisher, Niskayuna, NY (US); David Martin Mills, Niskayuna, NY (US); Stanley Chienwu Chu, Cupertino, CA (US); Hyon-Jin Kwon, Fremont, CA (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/350,424

(22) Filed: Feb. 9, 2006

(51) Int. Cl. G01H 11/06; H04R 31/00; G01R 3/00

(52) U.S. Cl. 73/649; 29/594

(57) ABSTRACT

A method of making a capacitive micromachined ultrasound transducer cell is provided. The method includes providing a carrier substrate, where the carrier substrate comprises glass. The step of providing the glass substrate may include forming vias in the glass substrate. Further, the method includes providing a membrane such that at least one of the carrier substrate, or the membrane comprises support posts, where the support posts are configured to define a cavity depth. The method further includes bonding the membrane to the carrier substrate by using the support posts, where the carrier substrate, the membrane and the support posts define an acoustic cavity.

### BACKGROUND

The invention relates generally to the field of diagnostic imaging, and more specifically to capacitive micromachined ultrasound transducers (cMUTs) and methods of making the same.

Transducers are devices that transform input signals of one form into output signals of another form. Commonly used transducers include light sensors, heat sensors, and acoustic sensors. An example of an acoustic sensor is an ultrasonic transducer, which may be implemented in medical imaging, non-destructive evaluation, and other applications.

Currently, one form of an ultrasonic transducer is a capacitive micromachined ultrasound transducer (cMUT). A cMUT cell generally includes a substrate, a bottom electrode that may be coupled to the substrate, a membrane suspended over the substrate by means of support posts, and a metallization layer that serves as a top electrode. The bottom electrode, membrane, and the top electrode define the vertical extents of the cavity, whereas the support posts define the lateral extents of the cavity. Typically, the substrate employed in a cMUT cell contains highly conductive material, such as heavily doped silicon. This results in higher values of parasitic capacitance and leakage currents in a cMUT cell. Also, the present day substrates, such as silicon, require high temperature processing, which in turn leads to more process steps. For example, while employing silicon substrate in a cMUT cell, the membrane and the support posts, which are typically oxides grown on the substrate, are coupled to one another by employing fusion bonding, which is done at temperatures above 900° C. If there is a mismatch in the coefficient of thermal expansions (CTEs) of the various layers of the cMUT cell, then processing at such high temperatures will tend to produce substrate warping and film delamination, which may reduce the device yield. In addition to the low device yield, the thermal stress generated at the interface of each layer will change the boundary conditions of the membrane and thus make the membrane design (e.g. resonant frequency and collapsed voltage) unpredictable. Some methods, such as high temperature annealing, will have to be used to alleviate the abovementioned high temperature induced effects but these processes require extra steps. Therefore, in order to have design flexibility for process integration, and also to reduce the cost of the fabrication process, it may be desirable to have a cMUT cell, which may be fabricated at lower temperatures with a fewer number of steps.

Further, it may be desirable to enhance the sensitivity and performance of the cMUT by reducing the parasitic capacitance and lowering the leakage current during operation as a transmitter and a receiver.

### BRIEF DESCRIPTION

In accordance with one aspect of the present technique, a method of making a capacitive micromachined ultrasound transducer cell is provided. The method includes providing a carrier substrate, where the carrier substrate comprises glass. Further, the method includes providing a membrane such that at least one of the carrier substrate, or the membrane comprises support posts, where the support posts are configured to define a cavity depth. The method further includes bonding the membrane to the carrier substrate by using the support posts, where the carrier substrate, the membrane and the support posts define an acoustic cavity.

In accordance with another aspect of the present technique, a method of making a capacitive micromachined ultrasound transducer cell includes providing a carrier substrate having a first surface and a second surface, where the carrier substrate comprises glass. The method further includes forming a via in the carrier substrate, where the via extends from the first surface to the second surface of the carrier substrate. Further, the method includes coupling a membrane to the carrier substrate to define an acoustic cavity, where a depth of the acoustic cavity is defined by support posts, and where one of the carrier substrate, or the membrane comprises the support posts.

In accordance with yet another aspect of the present technique, a method of making a capacitive micromachined ultrasound transducer array includes providing a glass substrate having a first surface and a second surface, where the first surface is partitioned into a plurality of portions. The method further includes forming vias in the glass substrate, where the vias extend from the first surface of the glass substrate to the second surface of the glass substrate. Further, the method includes depositing bottom electrodes on each of the portions of the first surface of the glass substrate, and coupling a plurality of membranes to the glass substrate such that each membrane is coupled to a portion of the glass substrate to define an acoustic cavity, and where a depth of the acoustic cavity is defined by support posts disposed within one of the glass substrate, or the membrane. Further, the method includes depositing contact pads on the first surface of the glass substrate such that the contact pads are formed on the portions of the glass substrate which does not employ the acoustic cavity, and where each contact pad is in electrical communication with a corresponding via.

In accordance with another aspect of the invention, a capacitive micromachined ultrasound transducer cell includes a glass substrate having a first surface and a second surface, and a membrane bonded to the first surface of the glass substrate, where one of the first surface of the glass substrate or the membrane defines a cavity.

In accordance with another aspect of the invention, a system includes a transducer array having a plurality of capacitive micromachined ultrasound transducer cells, where each cell includes a glass substrate having a first surface and a second surface, a membrane bonded to the first surface of the glass substrate, where one of the first surface of the glass substrate or the membrane includes support posts, and where the glass substrate, the membrane and the support posts define a cavity, an electrically insulating layer disposed in the cavity and coupled to the first surface of the glass electrode, and a bottom electrode disposed in the cavity.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic flow chart illustrating steps involved in an exemplary method for making a capacitive micromachined ultrasound transducer cell according to certain embodiments of the present technique;

FIG. 2 is a top view of an exemplary capacitive micromachined ultrasound transducer array illustrating the location of contact pads and vacuum holes according to certain embodiments of the present technique;

FIG. 3 is a cross-sectional side view of the capacitive micromachined ultrasound transducer array of FIG. 2 cut along the line 3-3 cut;

FIG. 4 is a cross-sectional side view illustrating the capacitive micromachined ultrasound transducer array of FIG. 3 having top electrodes and metal or dielectric layer disposed thereon to seal the vacuum holes;

FIG. 5-9 is a schematic flow chart illustrating steps involved in making the capacitive micromachined ultrasound transducer cell according to certain embodiments of the present technique;

FIGS. 10-12 are schematic flow charts illustrating steps involved in exemplary methods for making vias in the carrier substrate for the capacitive micromachined ultrasound transducer cell according to certain embodiments of the present technique;

FIG. 13 is a top view of an exemplary capacitive micromachined ultrasound transducer array employing a carrier substrate having bottom electrodes and vias, where the vias are coupled to contact pads disposed on a surface of the carrier substrate according to certain embodiments of the present technique;

FIG. 14 is a top view illustrating an exemplary capacitive micromachined ultrasound transducer array after electrical isolation etch according to certain embodiments of the present technique;

FIG. 15 is a cross-sectional side view of the array of FIG. 14; and

FIG. 16 is a cross-sectional side view of the array of FIG. 15 further employing top electrodes according to certain embodiments of the present technique.

### DETAILED DESCRIPTION

In many fields, such as medical imaging and non-destructive evaluation, it may be desirable to utilize ultrasound transducers that enable the generation of high quality diagnostic images. High quality diagnostic images may be achieved by enhancing the sensitivity and performance of the capacitive micromachined ultrasound transducers (cMUTs) by reducing the parasitic capacitance and lowering the leakage current during operation as a transmitter and a receiver.

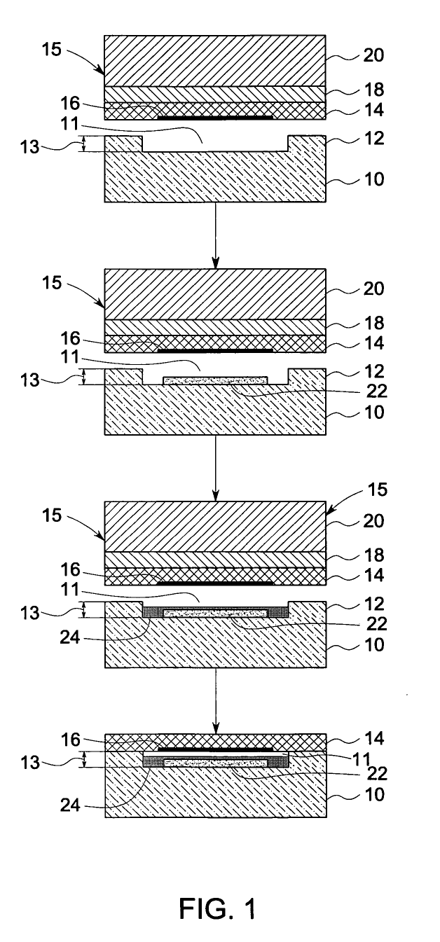

Turning now to FIG. 1, a schematic flow chart illustrating steps involved in a method of making a cMUT cell is illustrated. As will be appreciated by one skilled in the art, the figures are for illustrative purposes and are not drawn to scale. In the illustrated embodiment, the method begins by providing a carrier substrate 10. As will be described in detail below, in certain embodiments, the substrate 10 may include vias (not shown) to provide electrical communication between the two sides of the substrate 10. The carrier substrate 10 may include glass. In some embodiments, the glass may include a sodium rich glass. In an exemplary embodiment, the sodium rich material may include a borosilicate glass. The sodium rich glass may be deposited on a different substrate, which may or may not be sodium rich. The sodium rich glass may be formed by sputtering or spinning the sodium rich glass on a substrate, such as a glass substrate, a ceramic substrate, a plastic substrate, a polymer substrate, or a semiconductor substrate, such as a silicon substrate. The glass substrate may or may not be sodium rich. The semiconductor substrate may be either intrinsic or high resistivity.

As will be appreciated, a glass substrate exhibits lower electrical conductivity relative to semiconductor substrates, such as silicon, that are usually employed as carrier substrates in cMUT cells. Therefore, the glass substrate causes relatively lower parasitic capacitance as compared to its semiconductor counterparts. For conventional cMUTs using a semiconductor substrate, part of the electrostatic or acoustic energy for cMUT operation may be wasted in parasitic capacitance and may not be used efficiently for cMUTs. Whereas, when using a glass substrate, low values of parasitic capacitance are obtained and may enhance the device performance and robustness by eliminating any possible leakage paths.

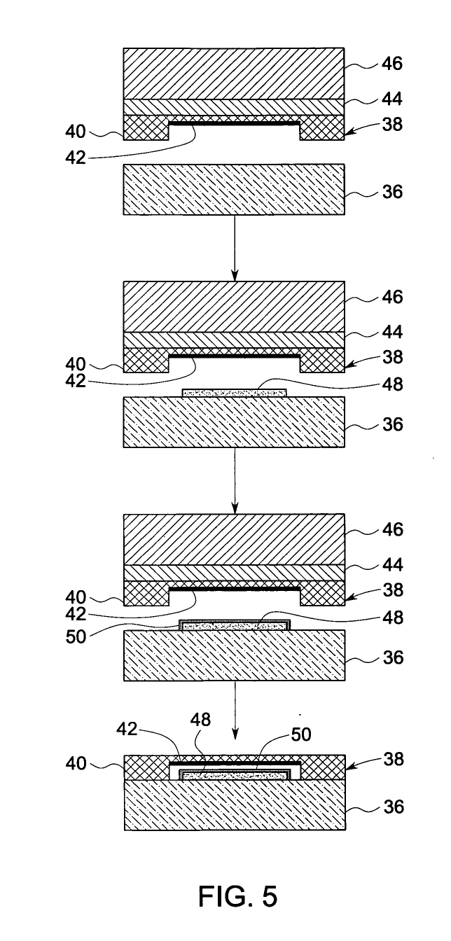

The carrier substrate 10 may include support posts 12. Further, a membrane or a diaphragm 14 may be disposed on and coupled to the support posts 12. Alternatively, the membrane 14 may include support posts 12, as illustrated in the embodiment of FIG. 5. The support posts 12 may be configured to define a cavity 11 having a cavity depth 13. Also, the support posts 12 define the lateral extents of the cavity 11. Generally, the height of the support posts 12 is of the order of tenths to tens of micrometers. The support posts 12 may be made by, for example, etching away a portion of the carrier substrate 10. Alternatively, the support posts 12 may be made by depositing and/or patterning a film (not shown) on the membrane 14. As will be described in detail below, the support posts 12 may include a material, which may facilitate bonding between the membrane 14 and the carrier substrate 10. In some embodiments, the support posts 12 may include the material of the carrier substrate 10 or the membrane 14. In other embodiments, the support posts 12 may be made of a material, such as, but not limited to metal, metal alloys, glass, plastic, polymer, and semiconductor materials. Semiconductor materials may include silicon nitride, silicon oxide, single crystal silicon, epitaxy silicon, or polycrystalline silicon.

Further, in embodiments where the support posts 12 are made in the carrier substrate 10, an oxide layer may be deposited on the top surface of the support posts 12, such that the membrane is coupled to the oxide and is not in direct contact with the carrier substrate 10. Whereas, as will be described in detail with regard to FIG. 5, in embodiments where the membrane 14 includes the support posts 12, the membrane may be coupled directly to the carrier substrate 10. In both the embodiments, the carrier substrate 10, the support posts 12 and the membrane 14 define an acoustic cavity 11. In addition, depending on the micromachining methods employed to fabricate the cMUT cell, the membrane 14 may be fabricated employing the materials such as, but not limited to, silicon nitride, silicon oxide, single crystal silicon, epitaxy silicon, polycrystalline silicon, and other semiconductor materials. The thickness of the membrane 14 may be, for example, approximately in the range of 0.1 to 10 micrometers. The membrane 14 may include a semiconductor material, such as silicon. In some embodiments, the membrane 14 may include a heavily doped single crystal silicon, poly crystal silicon, or epi-silicon. In these embodiments, the membrane 14 may be deposited on a silicon wafer.

Further, the step of providing the membrane 14 may also include growing or depositing an electrically insulating layer 16 to the membrane 14. As illustrated, the electrically insulating layer 16 is disposed inside the acoustic cavity 11 when the membrane 14 is coupled to the carrier substrate 10. In these embodiments, the depth of the acoustic cavity 11 is defined between the surfaces of the electrically insulating layer 16 and the surface of the bottom electrode 22 disposed inside the cavity 11. The electrically insulating layer may be grown and/or patterned on the membrane 14 for electrical isolation between the bottom electrode 22 and the membrane 14. In these embodiments, the electrically insulating layer 16 may include an electrically non-conducting materials, such as silicon nitride, or an oxide, such as a high temperature oxide, a low pressure chemical vapor deposited oxide, a plasma enhanced chemical vapor deposited oxide, or a thermally grown oxide. The dielectric layer may be deposited on the membrane 14, followed by polishing and/or lithography.

As will be appreciated by one skilled in the art, in the fabrication of the cMUT cell, the membrane 14 may be integrated with a pre-fabricated SOI (a Silicon on Insulator) wafer 15 including a silicon substrate (membrane 14), a buried oxide (box) layer 18 and a silicon handle wafer 20. In the illustrated embodiment, the membrane 14 may be coupled to a buried oxide (box) layer 18 prior to being bonded to the glass substrate 10. The buried oxide (box) layer 18 may in turn be coupled to a handle wafer 20 to form a SOI wafer 15. As will be appreciated, instead of the SOI wafer 15, a heavily doped silicon wafer (not shown) may be integrated with the membrane 14. Similarly, in the illustrated embodiments of FIGS. 1, 5, 6, 7, 8 and 9, the SOI wafers and the heavily doped silicon wafers may be employed interchangeably.

Further, as illustrated a bottom electrode 22 may be disposed on the carrier substrate 10, such that the bottom electrode 22 is disposed within the cavity 11. In this embodiment, the bottom electrode 22 and the membrane 14 bound the acoustic cavity 11. The bottom electrode 22 may include an electrically conductive material, such as aluminum, or an electrically conductive polymer. Further, the thickness of the bottom electrode 22 may be, for example, approximately in a range of from about tenths of micrometers to a few micrometers.

Additionally, a dielectric layer 24 may surround the bottom electrode 22, such that the bottom electrode 22 may not come in contact with the surrounding support posts 12, or with the electrically insulating layer 16. Although not illustrated, in an alternate embodiment, the dielectric layer, such as the dielectric layer 24, may be disposed only on the top portion of the bottom electrode 22, which is facing the membrane and may not cover the side portions of the bottom electrode 22. The dielectric layer 24 may include, for example, silicon oxide or silicon nitride. In some embodiments, the metallization to deposit the bottom electrode 22 may be performed prior to depositing the dielectric layer 24. Although the illustrated embodiments of FIGS. 1, 5, 6, 7 and 8 depict the cMUT cells employing both the insulating layer, such as the insulating layers 16, 42, 58, 70, 84, as well as the dielectric layer, such as dielectric layers 24, 50, 64, 76, 92, it should be noted that, in certain embodiments, only one of these layers may be employed to provide electrical insulation between the bottom electrode and the membrane.

Subsequently, the SOI wafer 15 including the membrane 14, the buried oxide layer 18 and the handle wafer 20, is coupled to the carrier substrate 10. The membrane 14 may be coupled to the carrier substrate 10 or the support posts 12 by employing low temperature bonding techniques, such as anodic bonding, a solder bonding, a chemical bonding, such as very slight etch (VSE), or combinations thereof. The bonding temperature for such low temperature bonding techniques may be in a range from about 25° C. to about 600° C. As will be appreciated, at such low temperatures, there are reduced residual stresses in the system, which otherwise may arise at high temperatures due to mismatch in the coefficient of thermal expansion of the various components in the system, such as the membrane 14, the carrier substrate 10 or the support posts 12. The coefficient of thermal expansion of glass is about 3.9 ppm/° C. and the coefficient of thermal expansion of silicon, which is usually the material employed in membrane 14, is about 3.3 ppm/° C. Hence, the coefficient of thermal expansion values of the two components are compatible at low temperatures, such as less than about 600° C. Also, low temperature processing permits the integration of sensors having cMUT cells with other complementary metal-oxide semiconductor (CMOS) electronics.

Also, at low temperatures, the bonding does not pose any limitation in terms of metallization steps. That is, unlike fusion bonding, where the metallization steps for the cMUT cell to deposit, for example, electrodes, cannot be done prior to the fusion bonding of the carrier substrate 10 and the SOI wafer 15. Whereas, in the low temperature bonding, the two steps can be independent of each other. Therefore, the electrodes may be formed either before or after forming the acoustic cavity 11 by bonding the carrier substrate 10 and the SOI wafer 15.

As noted above, the carrier substrate 10 may include a sodium rich glass. In low temperature bonding techniques, such as, anodic bonding, typically a potential is applied across the glass substrate-SOI wafer composite to generate an electric field that drives the sodium ions in the glass away from the interface of the glass substrate-SOI wafer composite, thereby forming a sodium depletion zone at the interface of the glass substrate 10 and the SOI wafer 15. As a result of the sodium ions migrating towards the glass substrate 10, the depletion zone becomes rich in oxygen molecules that are left behind by migrating sodium ions. These oxygen molecules from the glass diffuse into the silicon of the SOI wafer 15 to form a permanent covalent bond with silicon of the SOI wafer 15 by forming a layer of amorphous silica. As will be appreciated, the covalent bonds are extremely strong. For anodic bonding, either of the carrier substrate 10 or the SOI wafer 15 may be maintained at the positive polarity and the other component of the glass substrate-SOI wafer 15 composite may be maintained at the negative polarity. In an exemplary embodiment, where negative polarity is applied to the glass substrate 10, a voltage in a range of about 500 volts to about 1500 volts may be applied at atmospheric pressure to achieve an anodic bonding with a bonding temperature of about 300° C. to about 450° C. In another embodiment, the anodic bonding may be performed at 400° C. by applying a voltage of about 1000 volts. The bond strength may vary depending upon the bonding parameters, such as polarities of the bonding components, bonding pressure, bonding temperature, bonding time, and the like.

Advantageously, for anodic bonding and other low temperature bondings noted above, the tolerance for surface flatness is greater than that of the fusion bonding. Therefore, these low temperature bondings may not require smoothing or polishing of the surface prior to bonding, thereby reducing the number of steps and cost of the manufacturing process. The tolerance for surface flatness for the low temperature bondings may be of the order of about tens to hundreds of nanometers.

In certain embodiments, the formation of anodic bond may be verified by the change in color of the bond region. For example, appearance of black color in the bonded regions may indicate the formation of anodic bond.

Other low temperature bonding techniques, such as one or more of solder bonding, chemical bonding, eutectic bonding, thermo-compression bonding, glass-frit bonding, or polymer bonding may be employed to bond the carrier substrate 10 to the SOI wafer 15. Alternatively, the carrier substrate 10 and the SOI wafer 15 may be bonded using intermediate layer, such as a metal layer, an alloy layer, or a polymer layer. Such intermediate layers may form a bond with both the carrier substrate 10 and the SOI wafer 15 at temperatures in a range from about 25° C. to about 600° C. In one embodiment, the intermediate layer may form a bond with the carrier substrate 10 and the SOI wafer 15 at a temperature of less than about 550° C. As will be described in detail below, in an exemplary embodiment, the intermediate layer material may be employed in the support posts 12. In this embodiment, the support posts 12 may be deposited on one of the carrier substrate 10 or the membrane 14, and upon bonding may form a bond with the other component, thereby coupling the two components to define an acoustic cavity 11.

As will be appreciated, thermo-compression bonding includes the joining of two surfaces via the welding of a layer of a metal on each surface. Thermo-compression bonding may employ gold as the metal. Further, a suitable adhesion layer may also be employed with the layer of the metal. Thermo-compression bonding requires an application of a pressure on a surface at a temperature in a range from about 300° C. to about 400° C. Due to the low temperatures (˜300° C.) and moderate pressures (10⁶Pa), the process is readily compatible with other process steps, such as metallization. Advantageously, thermo-compression bonding offers relatively low outgassing for sealing of evacuated cavities 11.

In another embodiment, glass-frit bonding may be employed at a temperature in a range from about 400° C. to about 650° C. and a pressure of about 10⁵Pa. Typically, a glass layer is applied between the components to be bonded. For example, the glass layer may be employed between the support posts and one of the membrane 14 and the carrier substrate 10. The glass layer may be applied as a preform, a spin-on, a screen print, a sputtered film, or the like. Further, the glass layer may be patterned to define the bonding areas. The glass-frit bonding may be performed in vacuum, for example, for creating sealed evacuated cavities. As will be described in detail below, by carrying out the bonding process in a vacuum, the additional step of evacuating the cavity after bonding the carrier substrate 10 and the membrane 14 may be prevented, thereby reducing the number of steps involved in the process.

Alternatively, solder bonding may be employed to form the cavity 11. The solder bonding process works by re-flowing low melting point metals to form a seal. Solder bonding may employ one or more metals, such as gold, tin, copper, lead, or indium. The metals or metal alloys may be applied by various thin film deposition techniques. The technique differs from thermo-compression bonding in that the metallic intermediate layer needs to be melted for solder bonding. Advantageously, the solder bonding is tolerant to particles and surface roughness.

In other embodiments, the cavity 11 may be formed by bonding the respective surfaces by employing chemical or adhesive bonding. As will be appreciated, the various adhesives, such as epoxies, silicones, photoresists, or polyimides, may be used to form the adhesive bonds. In-situ alignment can be used with this bonding technique. The adhesive may be applied by coating techniques, such as spinning or spraying. Further, the adhesive bonding may be carried out at a between room temperature to about 400° C., depending on the adhesive being employed and the pressure applied. The adhesive bonding is tolerant to particles and surface roughness.

Further, eutectic bonding may be applied to form the cavity 11 by bonding the support posts 12 with the carrier substrate 10 or the membrane 14. As will be appreciated, the eutectic temperature of a two-material system corresponds to the lowest melting point composition of the two materials. In eutectic bonding, the two materials of the eutectic system are separately coated on the two parts, which are to be bonded to form the acoustic cavity 11. Subsequent to coating, the parts are heated and brought in contact, diffusion occurs at the interface and alloys are formed to create a bond. As will be appreciated, the eutectic composition alloy at the interface has a lower melting point than the materials either side of it, thereby restricting the melting to a thin layer. In some embodiments, the eutectic materials may include a gold-tin eutectic composition having a melting point of about 363° C., or a lead-tin eutectic composition having a melting point of about 183° C.

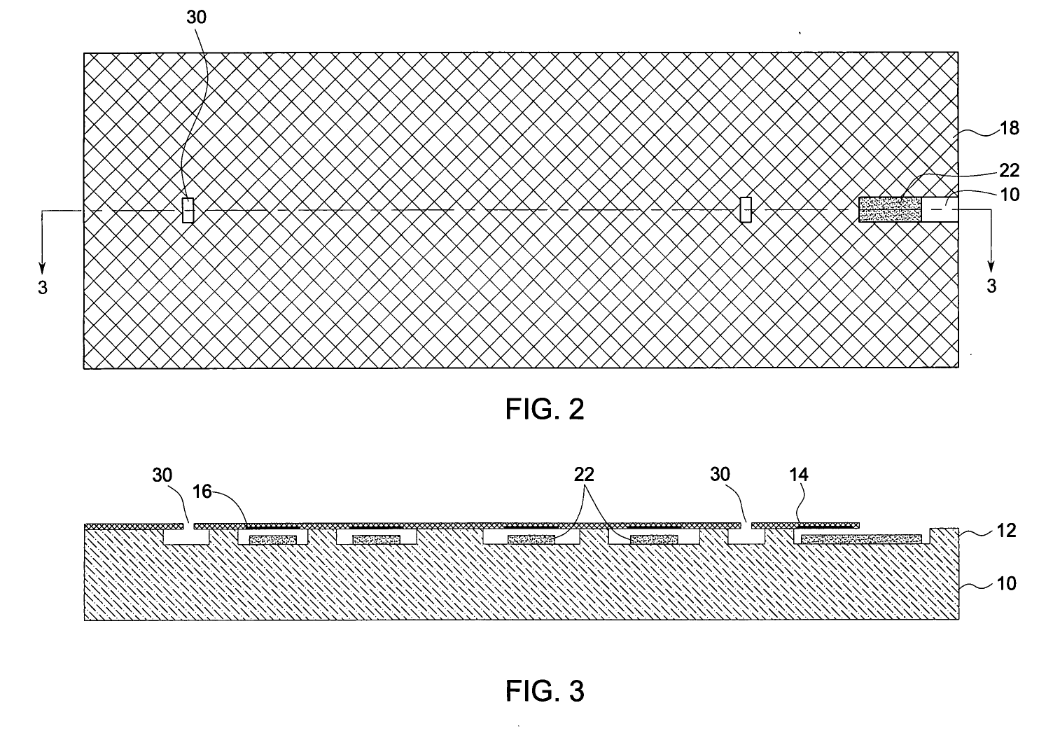

Further, force may be applied for a hermetic or vacuum sealed bonding. In some embodiments, the force may be applied to compensate for the surface roughness or non-flatness of the membrane 14, the carrier substrate 10, or the support posts 12. The vacuum sealed cavity, as described below with regard to FIG. 2, may be formed by in-situ sealing of the cavity during the chemical vapor deposition of a dielectric layer, or a metal layer in vacuum. In certain embodiments, the vacuum hole sealing step may be optional as in-situ vacuum sealing may be performed when employing the low temperature bonding in a vacuum.

Additionally, to enhance the bond strength, one or more of the carrier substrate 10, the support posts 12, or membrane 14 may be subjected to surface treatments prior to the step of bonding to remove impurities from the surface to enhance bonding between the components. In one embodiment, the surface treatment may include sputtering, or etching. For example, the surfaces of support posts 12 may be treated prior to bonding, by plasma etch.

Although not illustrated, subsequent to forming the lower temperature bond to bond the SOI wafer 15 to the carrier substrate 10, the handle wafer 20 and the box layer 18 may be removed. The handle wafer 20 may be removed by employing processes, such as mechanical polishing or grinding followed by wet etching with chemicals such as, but not limited to, tetramethyl ammonium hydroxide (TMAH), potassium hydroxide (KOH), and Ethylene Diamine Pyrocatechol (EDP). Following removal of the handle wafer 20, the oxide box layer 18 may be removed by buffered hydrofluoric acid (BHF). This may be followed by sealing the cavity in a vacuum, and depositing the top electrode.

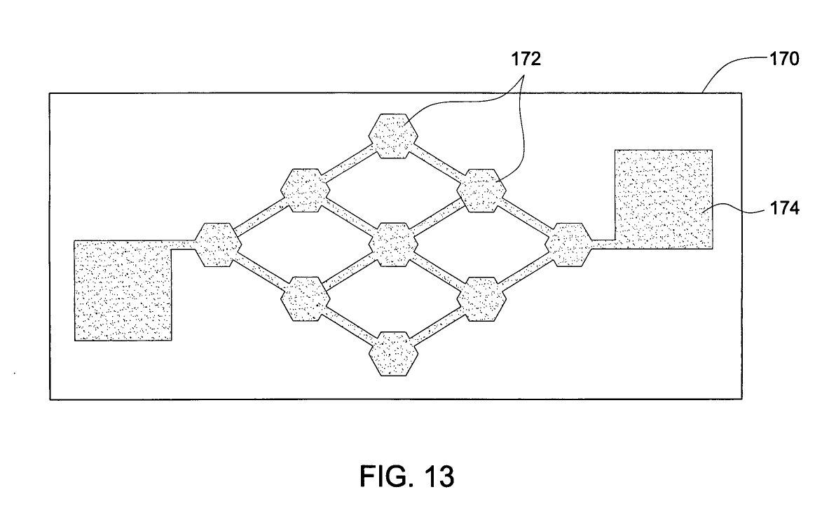

In an array of cMUT cells, such as the cMUT cell illustrated in FIG. 1, subsequent to removing the handle wafer 20 and the box layer 18, the membrane 14 is patterned to electrically isolate the cMUT cells from each other and to define vacuum sealing holes 30. FIG. 3 illustrates a cross-sectional view of a CMUT array of FIG. 2 taken along the line 3-3, employing a plurality of cMUT cells. In the illustrated embodiment, the locations of the bottom electrodes 22, and the vacuum holes 30 with respect to the cMUT cells are depicted. The bottom electrodes 22 are generally patterned as shown in FIG. 13. Although not illustrated, the bottom electrodes 22 are in configuration that will be described in greater detail with regard to FIG. 13.

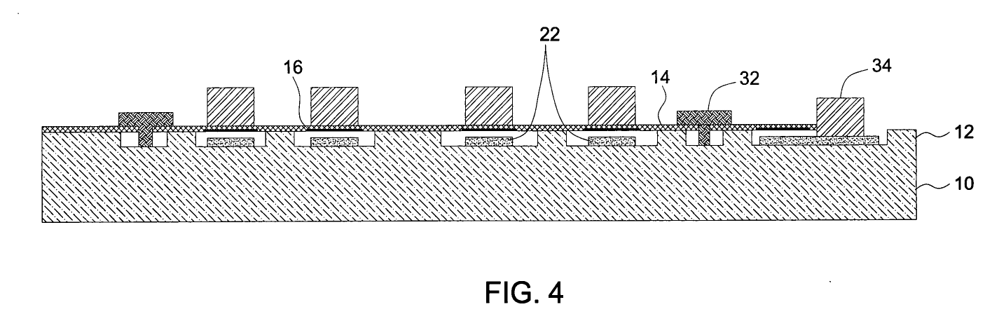

Subsequently, as illustrated in FIG. 4 dielectric layer 32 may be deposited in the vacuum holes 30 to seal the holes. The dielectric layer 32 may be deposited in the form of a layer that may be patterned to cover the vacuum holes 30. In one embodiment, photolithography may be employed to pattern the dielectric layer 32. Subsequently, metallization is performed to deposit top electrode 34. The top electrode 34 may be formed by depositing a layer of metal, and subsequently patterning the layer to retain the metal at depicted locations. Alternatively, in one embodiment, the vacuum holes 30 may be sealed by employing the same material as the material for the top electrode layer 34. In this embodiment, the sealing of the vacuum holes 30 and deposition and patterning of the top electrode layer 34 may be carried out simultaneously to further simplify the processing.

FIG. 5 illustrates an alternate embodiment of the method of making a cMUT as illustrated in FIG. 1. In the illustrated embodiment, a carrier substrate 36, and a membrane 38 is provided. In this embodiment, the support posts 40 are not initially coupled to the carrier substrate 36, but are built into the membrane 38. Also, an electrically insulative layer 42 is coupled to the membrane 38. Further, a box layer 44 and a handle wafer 46 may be coupled to the membrane 38 of the SOI wafer. Bottom electrode 48 may be deposited on the carrier substrate 36 using metallization and patterning. Subsequently, isolation layer 50 may be deposited on the bottom electrode 48. The isolation layer may be an electrically non-conductive layer and may include a dielectric material or an oxide.

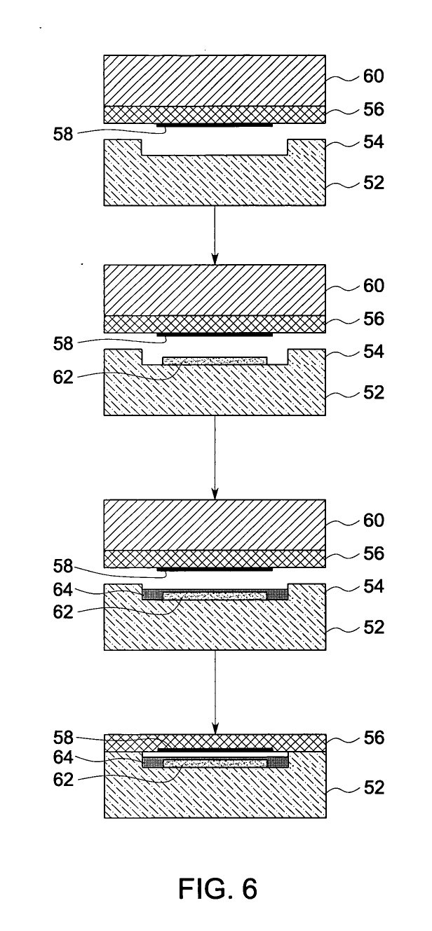

FIG. 6 illustrates yet another embodiment where the carrier substrate 52 having support posts 54 is provided. In the illustrated embodiment, the membrane 56 is coupled to an electrically insulating layer 58 on one side and to a handle wafer 60 on the other side. Since the SOI wafer is generally expensive, the present embodiment is relatively cost effective as compared to the embodiments illustrated in FIGS. 1 and 5. Further, in the illustrated embodiment, a bottom electrode 62 is deposited on the carrier substrate 52.

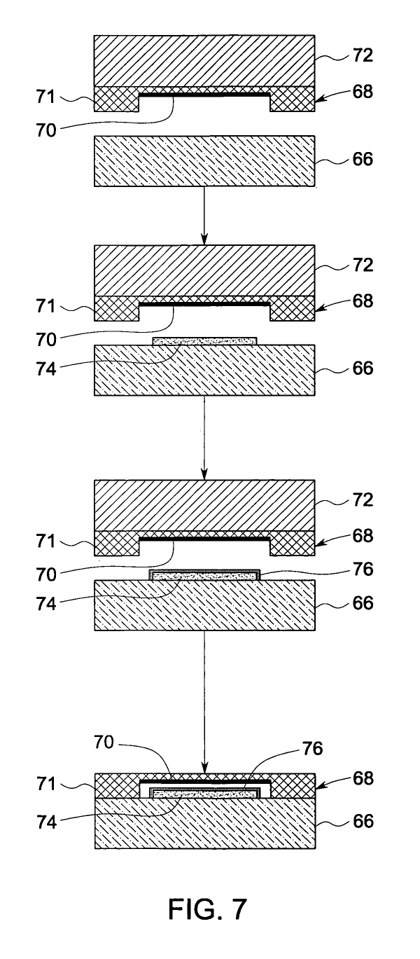

FIG. 7 illustrates an alternate embodiment of the method illustrated in FIG. 6. In the illustrated embodiment, a carrier substrate 66 is provided. Further, in this embodiment, the membrane 68 includes the support posts 71 and the electrically insulating layer 70 is provided. As with FIG. 6, in the illustrated embodiment, the membrane 68 is directly coupled to the handle wafer 72 without having the box layer disposed therebetween. Further, a bottom electrode 74 and an insulating layer, such as a dielectric layer 76, are disposed on the carrier substrate 66.

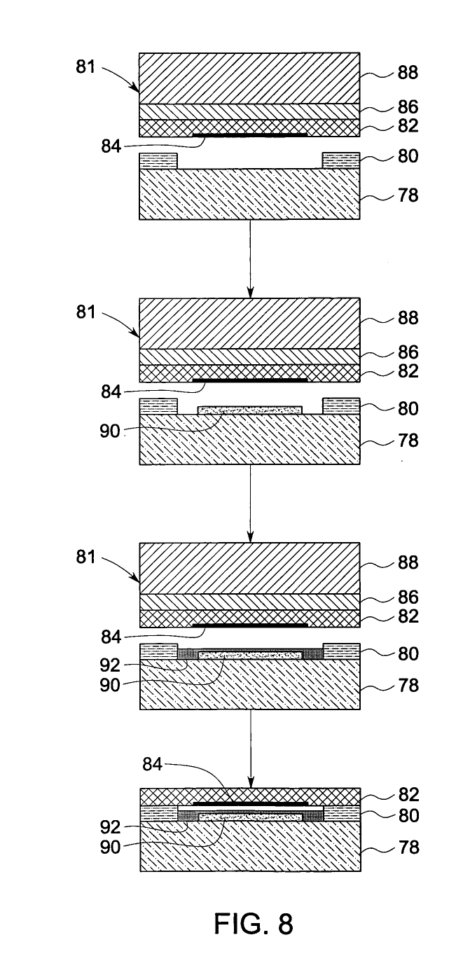

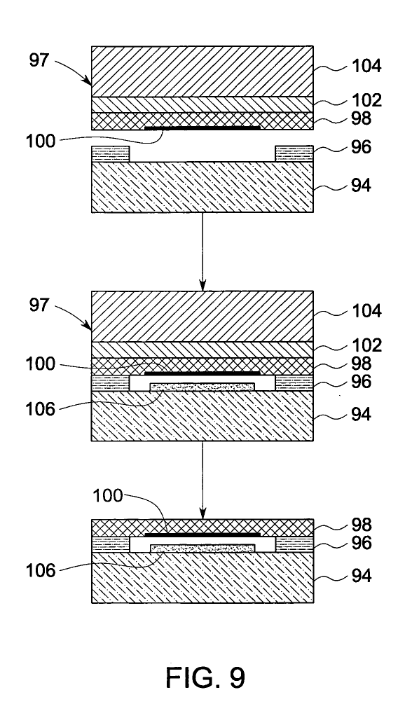

FIGS. 8 and 9 illustrate embodiments where the support posts may be formed from the bonding materials. In these embodiments, the support posts may be used to form the bond between the carrier substrate and the membrane. For example, compression bonding, solder bonding, or very slight etch (VSE) may be employed to bond the two components of the cMUT cell. As with the embodiments of FIGS. 1-7, in these embodiments, the cavity depth may be defined by the height of the support posts. Further, these support posts may be surface treated by using, for example, plasma etching, before bonding the carrier substrate and the membrane.

In some embodiments, the two surfaces, support posts and the membrane are brought together, for example, by wafer bonding equipments, to initiate the bonding interface. In these embodiments, a spontaneous bond may typically occur at some location in the bonding interface and may propagate across the interface. In certain embodiments, as the initial bond begins to propagate, a chemical reaction, such as polymerization that results in chemical bonds, may take place between materials of the support posts and those of the membrane and carrier substrate.

In the embodiment illustrated in FIG. 8, the carrier substrate 78 includes support posts 80. The support posts 80 may include one or more of a metal, a metal alloy, or glass frits. Further, a SOI wafer 81 having a membrane 82, a box layer 86 and a handle wafer 88 may be provided. The membrane 82 may be coupled to an electrically insulating layer 84. Further, a bottom electrode 90 having a dielectric layer 92 disposed thereon may be coupled to the carrier substrate 78.

FIG. 9 illustrates an alternate embodiment of the method illustrated in FIG. 8. In the illustrated embodiment, the carrier substrate 94 includes support posts 96. The support posts 96 may be similar to the support posts 80 (FIG. 8). Further, a SOI wafer 97 having a membrane 98, a box layer 102 and a handle wafer 104 may be coupled to the support posts. The membrane 98 further includes an electrically insulating layer 100. The cMUT cell further includes a bottom electrode 106 disposed on the carrier substrate 94.

As noted above, in certain embodiments, the carrier substrate may include one or more vias to electrically connect the components disposed on the opposite sides of the carrier substrate. The vias may extend through the thickness of the glass substrate. As will be appreciated by those of ordinary skill in the art, the vias are electrically conductive structures that interconnect different conductive or metallized layers, which are otherwise separated by one or more insulating layers. In this manner, electrical signals may be conducted between different layers or conductors in a multi-layer structure. In some embodiments, the vias may be configured to provide electrical communication between the membrane and electrical circuitry disposed on and coupled to the surface of the substrate, which is opposite to the surface that forms the acoustic cavity. That is, the vias may be used to electrically connect the cMUT cell to the opposite side of the carrier substrate. In turn, the opposite side of the carrier substrate may be bonded to an electronic circuit using packaging techniques, such as solder bumps. In certain embodiments, the vias may be formed on the substrate prior to fabrication of the cMUT on the substrate. Use of vias in glass substrate may eliminate several lithography steps, deep reactive ion etching, or other high temperature processes, which may be otherwise employed for fabrication of cMUTs having silicon-based substrate, thereby making the process cost effective.

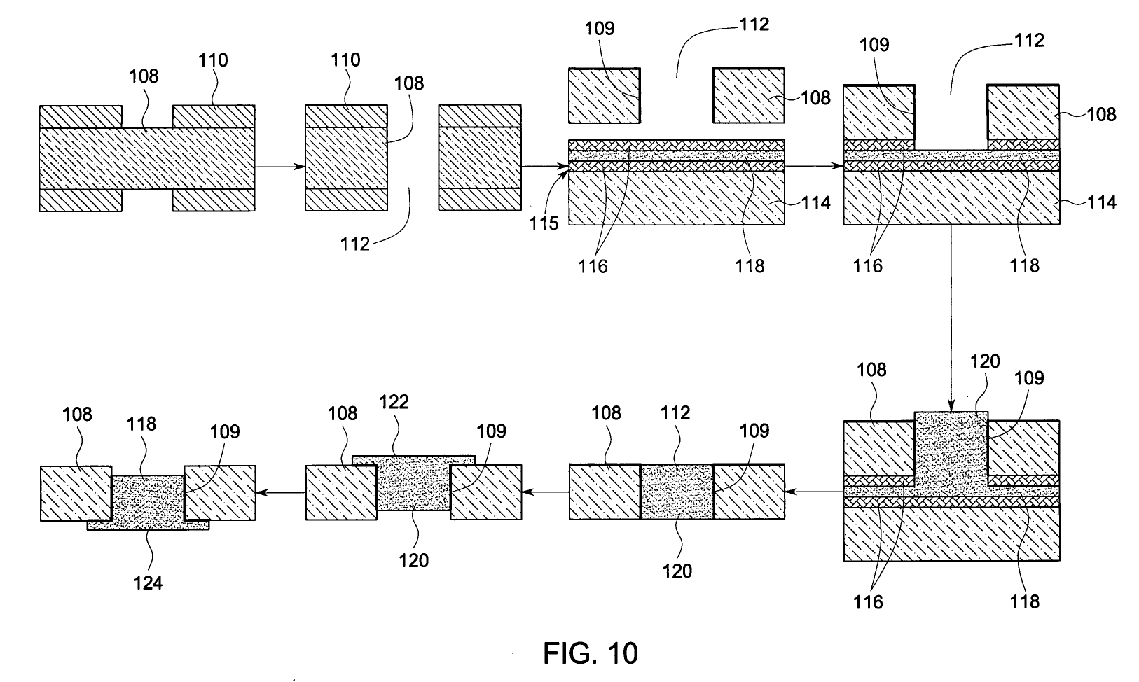

FIGS. 10-12 illustrate alternate embodiments of the method for making vias in the carrier substrate, such as the carrier substrate 10, 36, 52, 66, 78 or 94. The vias may have different cross sections, for example, the vias may have a circular cross section, an elliptical cross section, or any other geometrical shape. Further the vias may have different shapes. For example, the vias may be cylindrical or conical. Also, the orientation of the vias relative to the carrier substrate surface may vary. For example, the vias may be perpendicular to the surface of the carrier substrate. Alternatively, the vias may be skew relative to the surface of the carrier substrate. For example, the vias may converge on one surface and diverge on the other, that is, the vias may be oriented such that they may facilitate fan-out arrangement of devices.

In the embodiment illustrated in FIG. 10, a carrier substrate 108 is provided to form vias. The carrier substrate 108 may be an intrinsic or a low resistive silicon wafer. Lithography is performed to form the etch mask 110 and to define via diameter. The etch mask 110 may include one or more of a dielectric material, such as an oxide, or nitride, an elastic material, such as a photoresist, or a metal. Subsequently, vias 112 may be micromachined by employing processes, such as sand-blasting, ultrasound drilling, laser drilling, or other micromachining. In some embodiments, micromachining may be done by using wet etching, electrochemical etching, or dry etching. In certain embodiments, wet etching may employ one or more of KOH, EDP, or TMAH.

After forming the vias 112, the etch mask 110 is removed. Next, electrical insulation may be provided by performing thermal oxidization on the vias 112 to form oxide layer 109. Next, a handle wafer 114 is coupled to the carrier substrate 108. The handle wafer 114 may include a multi-layer structure 115 disposed thereon. The multi-layer structure 115 may include a metal layer 118 disposed between two layers of a photoresist 116. The structure 118 may serve as a seed layer for electroplating a metal in the via 112. Next, the patterned carrier substrate 108 is used as a photomask to expose the multi-layer structure 115 to ultraviolet (UV) light. Following exposure, the exposed layer of the photoresist from the structure 115 is washed away. Subsequently, metal electroplating is performed to deposit a conductive metal layer 120 in the via 112. The conductive metal layer 120 may include copper, nickel, or other metal which can be electroplated. Alternatively, molten solder, such as antimony, of any other conductive material may also be used as the interconnection in the via 108.

The handle wafer is removed using solvents or developers, and chemical mechanical polishing (CMP) is performed on both sides of the carrier substrate 108. by using etchants or solvents. Subsequently, wet metal etch and lithography is performed to define the interconnects 122 and 124 for the electronics on both sides of the via 108. Subsequently, cMUT may be fabricated on one side of the carrier substrate 108 using the methods described above. And an electronic packaging, such as a flip-chip, or a chip on board may be coupled to the other side of the carrier substrate 108.

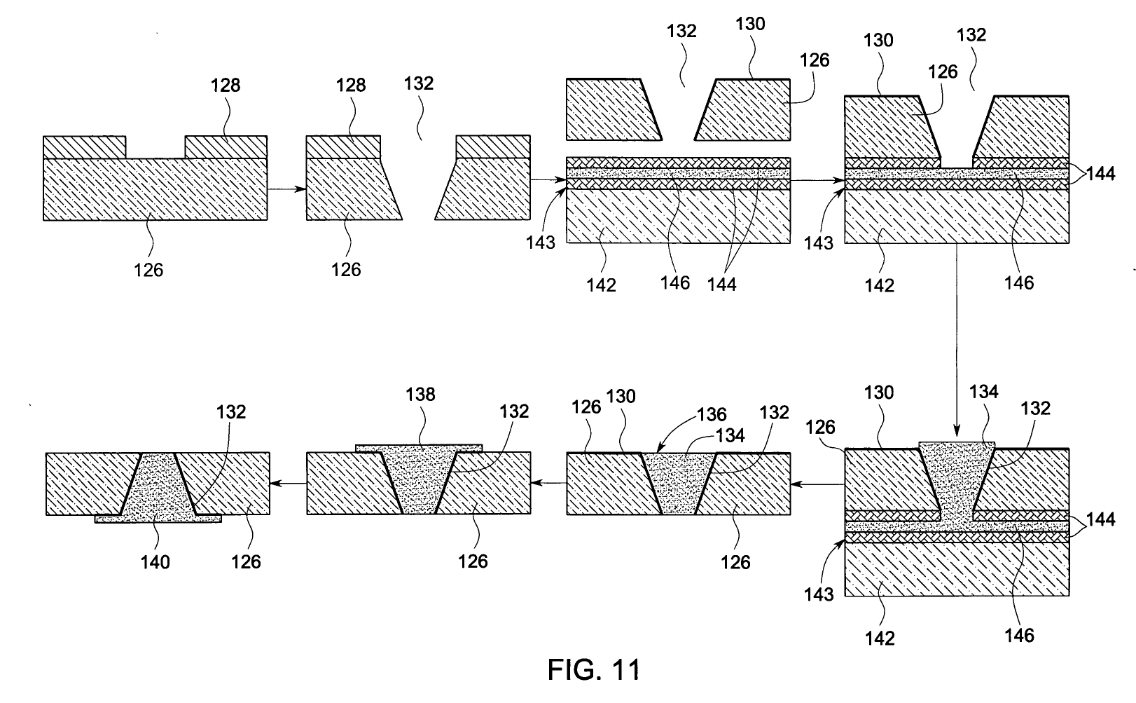

FIG. 11 illustrates an alternate embodiment of a method of making vias 132 in the carrier substrate 126. The carrier substrate 126 may be a glass wafer. The method includes providing a carrier substrate 126 and an etch mask 128. The etch mask 128 is patterned using photolithography. Subsequently, the via 132 is defined in the carrier substrate 126 by employing the processes described with regard to FIG. 10. It should be noted that the mask 128 may be disposed either on both sides of the substrate 126 or may be disposed only on one side of the substrate 126, as illustrated. Subsequently, the patterned photomask 128 is removed. Next, a seed layer 130 is deposited on the inner walls of the via 132 and on the surface of the carrier substrate 126. The seed layer 130 may include chromium, gold, nickel, copper, or other conductive materials. The seed layer 130 may be deposited using sputtering.

Subsequent to depositing the seed layer 130 and the carrier substrate 126 is disposed on a substrate handle wafer 142. The handle wafer 142 may include a multi-layer structure 143. The multi-layer structure 143 includes a seed metal layer 146 disposed between two photoresist layers 144. Next, one of the photoresist layer 144 is etched away by photolithography as discussed above. Next, a conductive metal layer 134 is electroplated to fill the via 132.

After the via 132 is filled with the conductive metal layer 134, the handle wager 142 is removed, and both the surfaces of the carrier substrate 126 are treated by CMP for surface roughness. Subsequently, lithography and wet etch are performed to define the interconnects on the two sides. Although not illustrated, a second mask may be employed to form the interconnects 138 and 140.

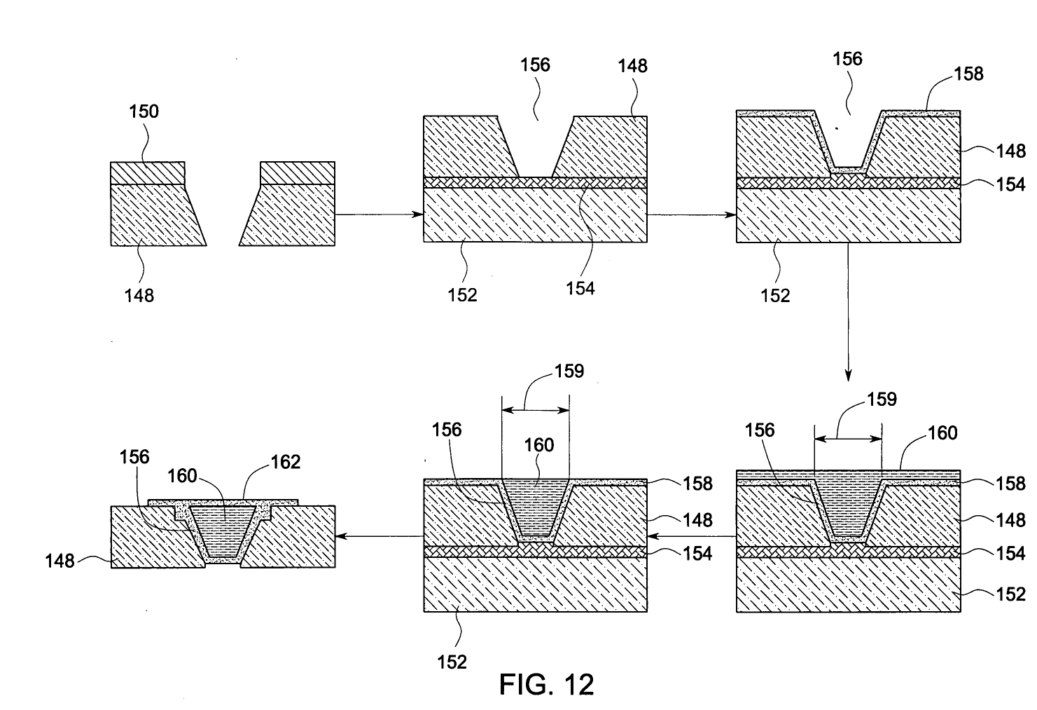

FIG. 12 is yet another alternate embodiment of the method of making vias in a glass carrier substrate, such as a carrier substrate 148. As with the embodiments of FIGS. 10 and 11, in FIG. 12 a via 156 is formed in the carrier substrate 148 by employing an etch mask 150. Subsequently, a handle wafer 152 having a photoresist layer 154 disposed thereon is coupled to the patterned carrier substrate 148. Next, a conductive material layer 158 is deposited on the walls of the via 156 by, for example, sputtering, for interconnection. The conductive material layer 158 may include chromium, aluminum, gold, nickel, copper, or combinations thereof. Subsequently, electroplating may be performed to increase the thickness of the layer 158 and fill the via 156 by the non-conductive material 160, such as polyimide. The metals used in electroplating may include one or more of tungsten, molybdenum, aluminum, chromium, nickel, or copper.

Alternatively, non-conductive polymers, such as polyimides, parylene, may be used to fill the via 156. The conductive polymers may be deposited in the via by employing deposition techniques, such as spinning, or chemical vapor deposition. Additionally, the conductive polymers may be cured after filling the via 156.

Subsequently, the non-conductive material 160 may be etched or polished to expose the layer 158. Further, metallization may be performed to cover the exposed portion 159 of the conductive material layer 158 and the handle wafer 152 may be removed and a cMUT may be fabricated on the same side of the carrier substrate 148.

FIGS. 13-16 illustrates a method of forming cMUT cell on a carrier substrate formed by one of the methods illustrated in FIGS. 10-12. The carrier substrate has vias and interconnects. FIG. 13 illustrates a top view of a carrier substrate 170 having a plurality of bottom electrodes 172 and a plurality of interconnects 174 disposed thereon. In the illustrated embodiment, the bottom electrode may be formed by metallization followed by lithography. The interconnects 174 may be similar to the interconnects 122 or 124 of FIG. 10, 138 or 140 of FIG. 11, or 162 of FIG. 12. Subsequently, a cMUT cell may be fabricated on the carrier substrate 170 by using the techniques described above with regard to FIGS. 1-9. In certain embodiments, the step of vacuum sealing using the chemical vapor deposition process may be removed. Instead, the vacuum inside the acoustic cavity may be achieved by bonding the cavity in a vacuum environment.

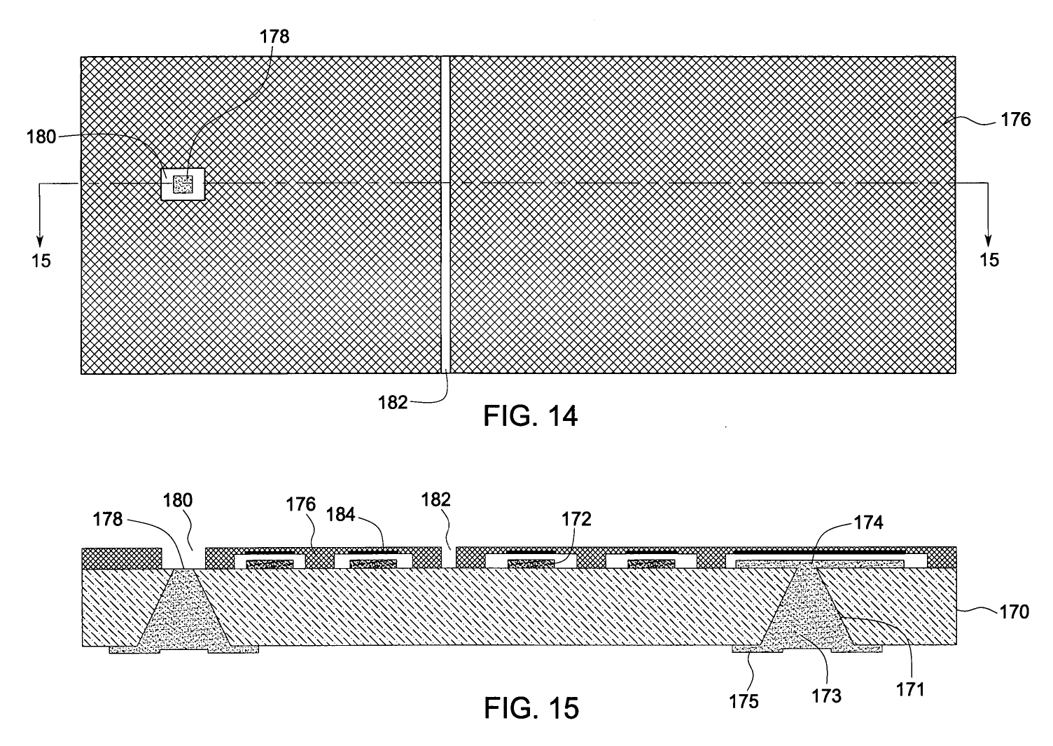

Further, a glass film may then be deposited on the carrier wafer 170. The glass film may be sputtered or spin deposited on the carrier substrate 170 and may be used to define the cavity depth for the acoustic cavity. Also, the glass film may be used to bonding the carrier substrate to the membrane. Alternatively, the membrane may be etched to define the support posts and cavity depth. As illustrated in FIGS. 14 and 15, after defining the cavity depth the carrier substrate 170 and the membrane 176 are bonded by using bonding techniques discussed above with regard to FIGS. 1-9. The bonding may be carried out in vacuum. The substrate 170 includes vias 171, while are filled with conductive materials 173 and form interconnects 175 at the two surfaces of the carrier substrate 170.

Subsequently, the membrane 176 may be patterned to open the top electrode at portions such as 180 to expose contact pads 178 on the carrier substrate 170. Also electrical isolation 182 may be formed between the elements of the cMUT array disposed on the carrier substrate 170. The electrical isolation may be formed by removing a portion of the membrane 176.

Further, in the illustrated embodiment, the cMUT cells include electrically insulating layer 184, which may be provided on the membrane 176. Although not illustrated, a conductive material may be deposited on the membrane 176 to form the top electrode. The metallization for the top electrode may also deposit at the portions from where the membrane 176 was removed. That is the metallization may also occur at openings 180, thereby forming electrical connects between the top electrode and the interconnects 178. Subsequently, lithography may be performed to pattern the top electrode.

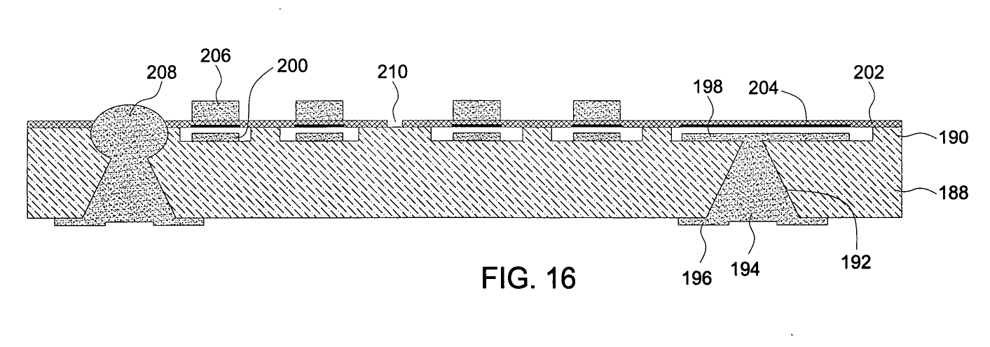

FIG. 16 illustrates an alternate embodiment of the cMUT array illustrated in FIG. 15. In the illustrated embodiment, the carrier substrate 188 includes support posts 190. The carrier substrate 188 also includes vias 192 which are filled with conductive materials as noted above with regard to FIGS. 10-12. The vias 192 further include interconnects 196 and 198 formed at the two opposite surfaces of the carrier substrate 188. The interconnects 198 may be configured to be used as bottom electrodes for the cMUT. Additional bottom electrodes 200 may be formed on the carrier substrate 188 by, for example, metallization followed by lithography. Additionally, the cMUT may include a membrane 202 having electrically insulating layer 204 disposed thereon, wherein each electrically insulating layer 204 corresponds to a bottom electrode 198 or 200. The cMUT may further include top electrodes 206. The top electrodes 206 may be formed by using the methods described above with regard to FIG. 15. As noted above, electrical connects 208 may be formed during the process of depositing top electrodes 206. Further, the cMUT may include electrical isolation 210, which are formed by removing a portion of the membrane 202 close to the support posts and away from the top and bottom electrodes 206 and 198.

Although the present technique is discussed with regard to cMUT devices. It should be noted that similar techniques, may be used for other semiconductor devices, such as membrane based devices. For example, vias of the present technique may also be employed in micro electro mechanical systems (MEMS). Additionally, MEMS or cMUT may be fabricated on the interconnects and electronic circuits may be attached underneath this substrate using flip chip or other packaging techniques.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method of making a capacitive micromachined ultrasound transducer cell, comprising:
providing a carrier substrate, wherein the carrier substrate comprises glass;
providing a membrane such that at least one of the carrier substrate, or the membrane comprises support posts, wherein the support posts are configured to define a cavity depth; and
bonding the membrane to the carrier substrate by using the support posts, wherein the carrier substrate, the membrane and the support posts define an acoustic cavity.

2. The method of claim 1, wherein the glass comprises a sodium rich glass.

3. The method of claim 2, wherein the glass comprises a borosilicate glass.

4. The method of claim 1, wherein the step of providing the carrier substrate further comprises providing a bottom electrode on the carrier substrate such that the acoustic cavity is bounded by the bottom electrode and the membrane.

5. The method of claim 1, wherein the step of providing the membrane further comprises growing an electrically insulating layer to the membrane such that the electrically insulating layer is disposed inside the acoustic cavity after the membrane is bonded to the carrier substrate.

6. The method of claim 1, wherein the step of bonding comprises one of an anodic bonding, a solder bonding, a chemical bonding, or combinations thereof.

7. The method of claim 6, wherein a bonding temperature is in a range from about 25° C. to about 600° C.

8. The method of claim 1, further comprising providing a surface treatment to one of the carrier substrate, the membrane, the support posts, or combinations thereof, prior to the step of bonding the membrane to the carrier substrate.

9. The method of claim 1, wherein the step of providing the carrier substrate further comprises forming a via in the substrate.

10. The method of claim 9, wherein the step of forming the via comprises:
forming a channel in the carrier substrate, wherein the channel extends through a thickness of the carrier substrate; and
disposing an electrically conductive layer in the channel, wherein the electrically conductive layer comprises an electrically conductive material.

11. The method of claim 10, wherein the step of disposing the electrically conductive material comprises:
forming a seed layer on inner walls of the via; and
electroplating the electrically conductive layer on the seed layer

12. The method of claim 11, wherein the seed layer comprises chromium, or gold, or both.

13. The method of claim 10, wherein the electrically conductive material comprises copper, or nickel, or both.

14. The method of claim 10, wherein the electrically conductive material comprises a conductive polymer.

15. The method of claim 10, wherein an orientation of the via is skewed relative to a surface of the substrate.

16. The method of claim 10, wherein an orientation of the via is perpendicular relative to a surface of the substrate.

17. A method of making a capacitive micromachined ultrasound transducer cell, comprising:
providing a carrier substrate having a first surface and a second surface, wherein the carrier substrate comprises glass;
forming a via in the carrier substrate, wherein the via extends from the first surface to the second surface of the carrier substrate; and
coupling a membrane to the carrier substrate to define an acoustic cavity, wherein a depth of the acoustic cavity is defined by support posts, and wherein one of the carrier substrate, or the membrane comprises the support posts.

18. A method of making a capacitive micromachined ultrasound transducer array, comprising
providing a glass substrate having a first surface and a second surface, wherein the first surface is partitioned into a plurality of portions;
forming vias in the glass substrate, wherein the vias extend from the first surface of the glass substrate to the second surface of the glass substrate;
depositing bottom electrodes on each of the portions of the first surface of the glass substrate;
coupling a plurality of membranes to the glass substrate such that each membrane is coupled to a portion of the glass substrate to define an acoustic cavity, and wherein a depth of the acoustic cavity is defined by support posts disposed within one of the glass substrate, or the membrane; and
depositing contact pads on the first surface of the glass substrate such that the contact pads are formed on the portions of the glass substrate which does not employ the acoustic cavity, and wherein each contact pad is in electrical communication with a corresponding via.

19. The method of claim 18, further comprising providing bottom electrodes on the first surface of the glass substrate.

20. The method of claim 18, further comprising depositing a dielectric layer on the plurality of membranes.

21. The method of claim 20, further comprising depositing top electrodes on the membrane.

22. The method of claim 18, further comprising depositing an insulating layer on the bottom electrodes.

23. The method of claim 18, further comprising forming vacuum holes in the plurality of membranes.

24. The method of claim 18, wherein coupling comprises anodic bonding, solder bonding, chemical bonding, or combinations thereof.

25. A capacitive micromachined ultrasound transducer cell, comprising;
a glass substrate having a first surface and a second surface; and
a membrane bonded to the first surface of the glass substrate, wherein one of the first surface of the glass substrate or the membrane defines a cavity.

26. The cell of claim 25, further comprising an electrically insulating layer disposed in the cavity, wherein the insulating layer is coupled to the membrane.

27. The cell of claim 25, wherein the glass substrate comprises a via, wherein the via is configured to provide electrical communication between the membrane and electrical circuitry coupled to the second surface of the glass substrate.

28. The cell of claim 25, further comprising a bottom electrode disposed in the cavity and coupled to the first surface of the glass substrate.

29. The cell of claim 25, wherein the membrane is coupled to the first substrate by anodic bonding.

30. A system, comprising:
a transducer array comprising a plurality of capacitive micromachined ultrasound transducer cells, each cell comprising:
a glass substrate having a first surface and a second surface;
a membrane bonded to the first surface of the glass substrate, wherein one of the first surface of the glass substrate or the membrane comprises support posts, and wherein the glass substrate, the membrane and the support posts define a cavity;
an electrically insulating layer disposed in the cavity and coupled to the first surface of the glass electrode; and
a bottom electrode disposed in the cavity.

31. The system of claim 30, further comprising contact pads disposed on the first surface of the glass substrate.

32. The system of claim 31, further comprising vias formed in the glass substrate, where the vias are in electrical communication with the contact pads.
